(19) United States
(12) Patent Application Publication
(10) Pub. No.: US 2004/0084669 A1
(43) Pub. Date: May 6, 2004

(54) [ACTIVE MATRIX ORGANIC LIGHT-EMITTING DIODE AND METHOD OF MANUFACTURING THE SAME]

(76) Inventors: HSIN-HUNG LEE, TAIPEI (TW); TIAO-HUNG HSIAO, KAOHSIUNG (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/250,036

(22) Filed: May 30, 2003

(30) Foreign Application Priority Data
Oct. 31, 2002 (TW) 91132243

(51) Int. Cl. H01L 35/24; H01L 51/00

(52) U.S. Cl. 257/40

(57) ABSTRACT

An active matrix organic light-emitting diode (AMOLED) and method of manufacturing the same. The AMOLED comprises of a thin film transistor with a gate, a gate insulation layer, a channel layer and a low-roughness source/drain metal terminal and an organic light-emitting diode with an anode layer, an organic light-emitting layer and a cathode layer. The gate of the thin film transistor is on a substrate, the channel layer is above the gate and the gate insulation layer is between the gate and the channel layer. The low-roughness source/drain metal terminal is positioned on each side of the gate covering a portion of the channel layer and the gate insulation layer. There is an ohmic contact layer between the channel layer and the low-roughness source/drain metal terminal. The anode layer of the organic light-emitting diode and one end of the low-roughness source/drain metal terminal are connected. The cathode layer is on the substrate and the organic light-emitting layer is positioned between the anode layer and the cathode layer. Furthermore, there is a passivation layer between the thin film transistor and the organic light-emitting layer.

### CROSS REFERENCE TO RELATED APPLICATIONS

This application claims the priority benefit of Taiwan application serial no. 91132243, filed on Oct. 31, 2002.

### BACKGROUND OF INVENTION

1. Field of Invention

The present invention relates to an organic light-emitting device. More particularly, the present invention relates to an active matrix organic light-emitting diode (AMOLED) and a method of manufacturing the same.

2. Description of Related Art

As electronic technologies continue to advance, video products, especially digital video or imaging devices are frequently used in our daily life. To be useful, all these digital video and imaging devices must have a clear display. Through the display, a user may obtain important information or control the operation of a specific device.

To adapt to the modern way of life, the body of most video or imaging equipment is progressively trimmed to shed weight and increase aesthetic appeal. Although the conventional cathode ray tube still have some advantages, disadvantages such as radiation, large power consumption and bulkiness has reduced its popularity. With great advance in optical-electrical technologies and semiconductor production technique, panel type display including the liquid crystal display and the active matrix organic light-emitting display has become very common.

Major techniques for fabricating a liquid crystal display have been around for a number of years and hence there is little room for major breakthroughs. On the other hand, active matrix organic light-emitting type of display is only recently developed. One major aspect of active organic light-emitting display is the special use of thin film transistor (TFT) technology to drive organic light-emitting diodes. Moreover, the driver integrated circuit (IC) is directly fabricated on the panel so that the display panel has a slim body and a low manufacturing cost. Hence, active matrix organic light-emitting displays may be used in mobile phone, personal digital assistant, digital camera, palm-top game player, portable DVD or car guidance system. In the future, an array of organic light-emitting diodes may even be applied to produce larger displays such as computer or flat-panel television.

In most active matrix organic light-emitting display, the source/drain metal terminal of the thin film transistor and the cathode of the organic light-emitting device are separated by an organic light-emitting layer of the organic light-emitting device and a passivation layer on the thin film transistor. If the surface of the source/drain metal terminal is too rough (for example, caused by arcing during a sputtering operation) or include some hillock protrusions (for example, resulted from heating aluminum), defects are likely formed in the passivation layer during deposition or the organic light-emitting layer during evaporation. When too many defects accumulates in the passivation layer and the organic light-emitting layer, the cathode and the source/drain metal terminal may form a short circuit leading to the production of a line or a point defect.

### SUMMARY OF INVENTION

Accordingly, one object of the present invention is to provide an active matrix organic light-emitting display and a method of manufacturing the same that prevents the formation of protrusions in source/drain metal terminal due to the presence of hillocks. The absence of protrusions in the source/drain metal terminal prevents the formation of defects when passivation material is deposited to form the passivation layer or organic light-emitting material is evaporated to form the organic light-emitting layer. By eliminating possible defects in the passivation layer and the organic light-emitting layer, the probability of a short circuit between the cathode and the source/drain metal terminal is minimized. Ultimately, the appearance of point or line defects on the display screen is greatly reduced.

To achieve these and other advantages and in accordance with the purpose of the invention, as embodied and broadly described herein, the invention provides an active matrix organic light-emitting display (AMOLED). The AMOLED includes a thin film transistor having a gate, a gate insulation layer, a channel layer and a low-roughness source/drain metal terminal and an organic light-emitting diode having an anode layer, an organic light-emitting layer and a cathode layer. The gate of the thin film transistor is on a substrate. The channel layer is on the gate. The gate insulation layer is between the gate and the channel layer. The low-roughness source/drain metal terminal is positioned on each side of the gate covering a portion of the channel layer and the gate insulation layer. Roughness level on the surface of the low-roughness source/drain metal terminal is smaller than the roughness level on the surface of a conventional source/drain metal terminal to eliminate hillock protrusions. Moreover, there is an ohmic contact layer between the channel layer and the low-roughness source/drain metal terminal. The anode layer of the organic light-emitting diode and one end of the low-roughness source/drain metal terminal are connected. The cathode layer is on the substrate. The organic light-emitting layer is positioned between the anode layer and the cathode layer. Furthermore, there is a passivation layer between the thin film transistor and the organic light-emitting layer.

This invention also provides a method of forming an active matrix organic light-emitting diode. First, a substrate is provided. A gate is formed on the substrate. Thereafter, a gate insulation layer is formed over the substrate covering the gate. A channel layer is formed on the gate and then a low-roughness source/drain metal terminal is formed on each side of the gate covering a portion of the channel layer. An anode layer is formed over the substrate such that the anode layer is connected to one end of the low-roughness source/drain metal terminal. A passivation layer is formed over the substrate covering the low-roughness source/drain metal terminals and the channel layer. Next, an organic light-emitting layer is formed over the substrate. Finally, a cathode layer is formed on the organic light-emitting layer.

In this invention, source/drain metal terminal with low surface roughness is formed on the substrate. The absence of protruding hillocks from the surface prevents the formation of defects in the passivation layer or the organic light-emitting layer during deposition or plating. Since the probability of forming an open circuit between the cathode and the source/drain metal terminal is greatly reduced, line or point defects rarely form on the display screen.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart showing the steps for producing an active matrix organic light-emitting diode according to one preferred embodiment of this invention.

FIG. 2 is a schematic cross-sectional view of an active matrix organic light-emitting diode according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

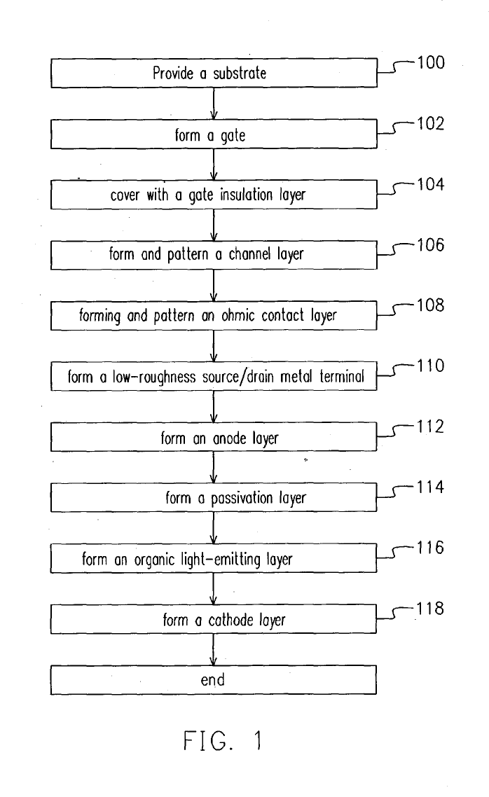

FIG. 1 is a flow chart showing the steps for producing an active matrix organic light-emitting diode (AMOLED) according to one preferred embodiment of this invention. To form an AMOLED, a substrate is provided in step 100 and then a gate is formed on the substrate in step 102. A gate insulation layer covering the gate and the entire substrate surface is formed in step 104.

In step 106, a channel layer made from a material such as amorphous silicon silicon

(α-Si) 1

is formed over the gate to serves as a channel for the thin film transistor ( ohmic contact layer made from a material such as an n⁺ amorphous silico channel layer to improve the electrical contact between the channel layer formed source/drain terminal.

In step 110, a low-roughness source/drain metal terminal made from a metal such as molybdenum (Mo) is formed over the over the ohmic contact layer on each side of the gate. The low-roughness source/drain metal terminal must have a surface roughness smaller than aluminum. However, the level of roughness of the source/drain metal terminal is based on the size of the source/drain metal terminal in the active matrix organic light-emitting diode. For a source/drain metal terminal having a size smaller than 3 ÂμmÃ□3Âμm, a surface roughness smaller than 400 Ã□s preferred.

In step 112, an anode layer made from a material such as indium-tin-oxide (ITO) is formed on one side of the gate above the gate insulation layer. In step 114, a passivation layer is formed over the channel layer and the source/drain metal terminal, that is, the thin film transistor. The passivation layer is, for example, a silicon nitride layer. In step 116, an organic light-emitting layer is formed over the substrate. In step 118, a cathode layer is formed over the organic light-emitting layer.

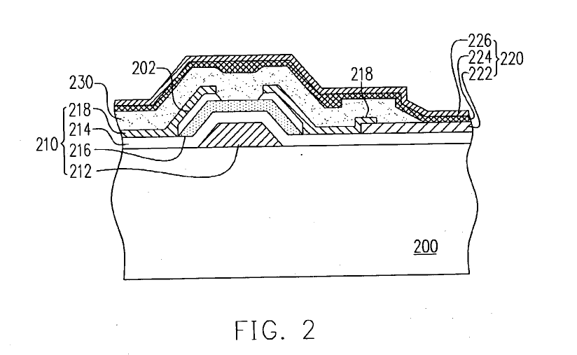

FIG. 2 is a schematic cross-sectional view of an active matrix organic light-emitting diode according to one preferred embodiment of this invention. As shown in FIG. 2, an active matrix organic light-emitting diode mainly comprises of a thin film transistor 210 and an organic light-emitting device 220. In this embodiment, the thin film transistor 210 includes a gate 212, a gate insulation layer 216, a channel layer 216 and a low-roughness source/drain metal terminal 218. The gate 212 is on a substrate 200. The channel layer 216 is located above the gate 212. The gate insulation layer 214 is positioned between the gate 212 and the channel layer 216 covering the gate 212 and the substrate 200. The low-roughness source/drain metal terminal 218 is located on each side of the gate 212 covering a portion of the channel layer 216 and the gate insulation layer 214. Furthermore, an ohmic contact layer 202 is formed between the channel layer 216 and the low-roughness source/drain metal terminal 218.

As shown in FIG. 2, the organic light-emitting device 220 includes an anode layer 222, an organic light-emitting layer 224 and a cathode layer 226. The anode layer 222 on the substrate 200 is connected to one end of the low-roughness source/drain terminal metal 218. The cathode layer 226 is above the substrate and the organic light-emitting layer 224 is located between the anode layer 222 and the cathode layer 226. Furthermore, a passivation layer 230 is formed between the thin film transistor 210 and the organic light-emitting layer 224.

In this invention, source/drain metal terminal with a low surface roughness is used. This prevents the arcing during a sputtering process or direct heating of the aluminum source/drain terminal from producing any protruding hillocks. The absence of protruding hillocks from the surface reduces the number of defects in the passivation layer or the organic light-emitting layer after a passivation material deposition or an organic light-emitting material plating process. Since the probability of forming an open circuit between the cathode and the source/drain metal terminal decreases with the number of defects, line or point defects rarely on the display screen is greatly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An active matrix organic light-emitting diode, comprising:
a thin film transistor having a gate, a gate insulation layer, a channel layer and a low-roughness source/drain metal terminal, wherein
the gate is on the substrate;
the channel layer is above the gate;
the gate insulation layer is between the gate and the channel layer and covers the gate and the substrate; and
the low-roughness source/drain metal terminal is located on each side of the gate covering a portion of the channel layer and the gate insulation layer;
an organic light-emitting device having an anode layer, an organic light-emitting layer and a cathode layer, wherein
the anode layer is connected to one end of the low-roughness source/drain metal terminal covering the substrate;
the cathode layer is above the substrate; and
the organic light-emitting layer is between the anode layer and
the cathode layer; and
a passivation layer between the thin film transistor and the organic light-emitting layer.

2. The active matrix organic light-emitting diode of claim 1, wherein the low-roughness source/drain metal terminal has a surface roughness smaller than an aluminum.

3. The active matrix organic light-emitting diode of claim 1, wherein the low-roughness source/drain metal terminal has a surface roughness smaller than 400 Ã□.

4. The active matrix organic light-emitting diode of claim 1, wherein the passivation layer includes a silicon nitride layer.

5. The active matrix organic light-emitting diode of claim 1, wherein material constituting the channel layer includes amorphous silicon.

6. The active matrix organic light-emitting diode of claim 1, wherein the diode may further include an ohmic contact layer between the channel layer and the low-roughness source/drain metal terminal.

7. The active matrix organic light-emitting diode of claim 6, wherein material constituting the ohmic contact layer includes n⁺ amorphous silicon.

8. An active matrix organic light-emitting diode, comprising:
a thin film transistor having a gate, a gate insulation layer, a channel layer and a low-roughness source/drain metal terminal, wherein the low-roughness source/drain metal terminal is positioned on each side of the gate covering a portion of the channel layer and the gate insulation layer;
an organic light-emitting device having an anode layer, an organic light-emitting layer and a cathode layer, wherein the anode layer is connected to one end of the low-roughness source/drain metal terminal covering the substrate; and
a passivation layer between the thin film transistor and the organic light-emitting layer.

9. A method of forming an active matrix organic light-emitting diode, comprising the steps of:
providing a substrate;
forming a gate over the substrate;
forming a gate insulation layer over the substrate covering the gate;
forming a channel layer over the gate;
forming a low-roughness source/drain metal terminal on each side of the gate covering a portion of the channel layer;
forming an anode layer over the substrate such that the anode layer is connected to one end of the low-roughness source/drain metal terminal;
forming a passivation layer over the substrate covering the low-roughness source/drain metal terminal and the channel layer;
forming an organic light-emitting layer over the substrate; and
forming a cathode layer over the organic light-emitting layer.

10. The method of claim 9, wherein the low-roughness source/drain metal terminal has a surface roughness smaller than an aluminum terminal.

11. The method of claim 9, wherein the low-roughness source/drain metal terminal has a surface roughness smaller than 400 Ã□.

12. The method of claim 9, wherein the passivation layer includes a silicon nitride layer.

13. The method of claim 9, wherein material constituting the channel layer includes amorphous silicon.

14. The method of claim 9, wherein before the step of forming a low-roughness source/drain metal terminal on each side of the gate, further includes forming an ohmic contact layer over the channel layer.

15. The method of claim 14, wherein material constituting the ohmic contact layer includes n⁺ amorphous silicon.

16. A method of forming an active matrix organic light-emitting diode, comprising the steps of:
providing a substrate;
forming a gate, a gate insulation layer and a channel layer over the substrate;
forming a low-roughness source/drain metal terminal on each side of the gate covering a portion of the channel layer;
forming an anode layer over the substrate such that the anode layer is connected to one end of the low-roughness source/drain metal terminal;
forming a passivation layer over the substrate covering the low-roughness source/drain metal terminal and the channel layer;
forming an organic light-emitting layer over the substrate; and
forming a cathode layer over the organic light-emitting layer.
